(19) United States
(12) Patent Application Publication
(10) Pub. No.: US 2019/0232431 A1
(43) Pub. Date: Aug. 1, 2019

(54) LASER PROCESSING METHOD

(71) Applicant: DISCO CORPORATION, Tokyo (JP)

(72) Inventors: Yuji HADANO, Tokyo (JP); Koichi KATAYAMA, Tokyo (JP); Keiji NOMARU, Tokyo (JP)

(21) Appl. No.: 16/253,872

(22) Filed: Jan. 22, 2019

(30) Foreign Application Priority Data
Jan. 30, 2018 (JP) 2018-013776

(51) Int. Cl. B23K 26/364; B23K 26/402; B23K 26/53; B23K 26/146; H01L 21/8258; B23K 26/16

(52) U.S. Cl. CPC B23K 26/364; B23K 26/402; B23K 26/53; B23K 2101/40; H01L 21/8258; B23K 26/16; B23K 26/146

(57) ABSTRACT

A laser processing method for performing groove processing by applying to a workpiece a laser beam of such a wavelength as to be absorbed in the workpiece includes: a protective member disposing step of disposing a protective member on an upper surface of the workpiece; a liquid layer forming step of forming a liquid layer on the upper surface of the workpiece; a laser beam applying step of applying the laser beam through the liquid layer to subject the upper surface of the workpiece to groove processing and to produce minute bubbles; and a debris removing step of removing debris from inside of grooves by rupture of the bubbles.

### BACKGROUND OF THE INVENTION

### Field of the Invention

The present invention relates to a laser processing method for processing a workpiece by applying to the workpiece a laser beam of such a wavelength as to be absorbed in the workpiece.

### Description of the Related Art

A wafer in which a plurality of devices such as integrated circuits (ICs) and large-scale integrated circuits (LSIs) are formed on a front surface while partitioned by a plurality of intersecting division lines (streets) is divided into individual device chips by utilizing division grooves which are formed by applying to the wafer a laser beam of such a wavelength as to be absorbed in the wafer along the division lines, and the device chips are utilized in electric apparatuses such as mobile phones, personal computers and illumination apparatuses.

In addition, when a laser beam of such a wavelength as to be absorbed in a wafer is applied to the wafer, so-called debris is generated and adheres to the upper surface of the wafer, thereby lowering the quality of the devices; in view of this, a protective member may be disposed on the upper surface of the wafer (see, for example, Japanese Patent Laid-open No. 2004-188475).

### SUMMARY OF THE INVENTION

According to the technology described in Japanese Patent Laid-open No. 2004-188475, the debris generated is restrained from adhering to the upper surface of the wafer. However, the debris may adhere to side walls formed inside division grooves formed by application of the laser beam, and the debris may remain on side walls of the device chips individually divided from the wafer. Then, there may arise a problem in which the debris remaining on the side walls of the device chip lowers the die strength of the device chip, or a problem in which part of the debris drops off the side walls of the device chip at the time of carrying out the device chip, possibly hampering wiring at the time of bonding the device chip onto a wiring frame.

Further, the problem in which the debris adheres to the side walls of the division grooves formed by application of the laser beam is generated also in the case where a glass plate is divided by laser beam application to produce cover glasses, thereby causing lowering in the quality of the cover glasses.

It is therefore an object of the present invention to provide a laser processing method for forming division grooves in a workpiece by application of a laser beam to the workpiece, by which adhesion of debris to side walls of the division grooves formed can be prevented.

In accordance with an aspect of the present invention, there is provided a laser processing method for performing groove processing by applying to a workpiece a laser beam of such a wavelength as to be absorbed in the workpiece, the laser processing method including: a protective member disposing step of disposing a protective member on an upper surface of the workpiece; a liquid layer forming step of forming a liquid layer on an upper surface of the protective member disposed on the upper surface of the workpiece, after the protective member disposing step is performed; a laser beam applying step of applying the laser beam through the liquid layer to subject the upper surface of the workpiece to groove processing and to produce minute bubbles; and a debris removing step of removing debris from inside of grooves by rupture of bubbles.

Preferably, the workpiece is a wafer in which a plurality of devices are formed on an upper surface while partitioned by a plurality of intersecting division lines, and the laser beam applying step includes applying the laser beam along the division lines. Preferably, the laser beam applying step includes applying the laser beam through a transparent plate disposed on an upper side of the liquid layer.

According to the present invention, the debris can be removed from the inside of the grooves formed by application of the laser beam, so that the debris would not remain on side walls of devices, and the die strength of the devices can be restrained from being lowered. In addition, since the protective member disposing step of disposing the protective member on the upper surface of the workpiece is conducted before the liquid layer forming step, damaging of outer peripheries of the devices can be restrained even if the laser beam is scattered by the bubbles produced.

The above and other objects, features and advantages of the present invention and the manner of realizing them will become more apparent, and the invention itself will best be understood from a study of the following description and appended claims with reference to the attached drawings showing some preferred embodiment of the invention.

### BRIEF DESCRIPTION OF THE DRAWINGS

FIGS. 1A and 1B are perspective views depicting a mode of carrying out a protective member disposing step in a laser processing method according to an embodiment of the present invention;

FIG. 2 is a general perspective view of a laser processing apparatus for carrying out the laser processing method according to the present embodiment;

FIG. 3 is an exploded perspective view depicting, in a dismantled state, a part of the laser processing apparatus depicted in FIG. 2;

FIG. 4A is a perspective view of a liquid jetting unit mounted to the laser processing apparatus depicted in FIG. 2;

FIG. 4B is an exploded perspective view of the liquid jetting unit;

FIG. 5 is a block diagram depicting an optical system of laser beam applying means mounted to the laser processing apparatus depicted in FIG. 2, and is a sectional view of the liquid jetting unit taken along X direction;

FIG. 6 is a perspective view for explaining a mode of carrying out a liquid layer forming step in the laser processing method according to the present embodiment;

FIG. 7A is a sectional view of the liquid jetting unit taken along Y direction, depicting a mode of carrying out a laser beam applying step; and

FIG. 7B is a partial enlarged sectional view of the liquid jetting unit, depicting a mode of carrying out a debris removing step.

### DETAILED DESCRIPTION OF THE PREFERRED EMBODIMENT

A laser processing method according to an embodiment of the present invention will be described in detail below, referring to the attached drawings. The laser processing method according to the present embodiment includes: a protective member disposing step of disposing a protective member on an upper surface of a workpiece; a liquid layer forming step of forming a liquid layer on the upper surface of the workpiece; a laser beam applying step of applying a laser beam through the liquid layer to subject the upper surface of the workpiece to groove processing and to produce minute bubbles; and a debris removing step of removing debris from inside of grooves by rupture of the bubbles. The steps will be sequentially described below.

### [Protective Member Disposing Step]

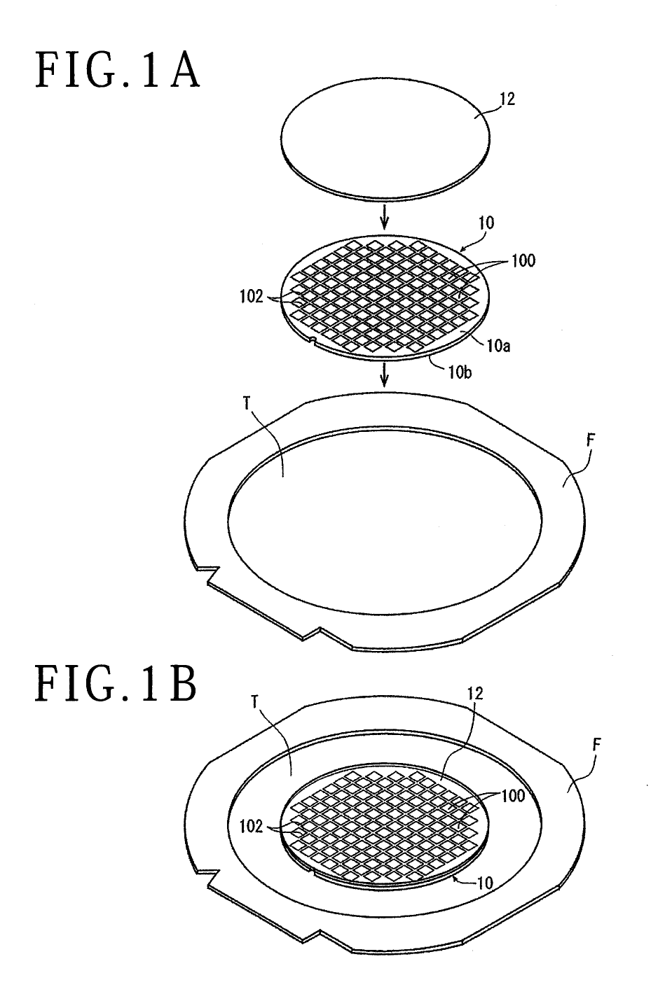

In performing the protective member disposing step in the present embodiment, first, a wafer 10 as a workpiece and a protective member 12 are prepared. As depicted in the center of FIG. 1A, the wafer 10 includes a disk-shaped semiconductor, and devices 100 are respectively disposed in a plurality of regions partitioned by division lines (streets) 102 formed in a grid pattern on an upper surface 10a of the wafer 10.

The protective member 12 is, for example, a polyvinyl chloride sheet which is formed in a disk shape the same in size as the wafer 10 in plan view and has a thickness of 10 to 50 μm. The protective member 12 is adhered to the upper surface 10a of the wafer 10 prepared, whereby the protective member disposing step is completed. Note that the protective member 12 is not limited to the polyvinyl chloride sheet, and may be selected from sheet members of, for example, polyethylene terephthalate (PET), acrylic resin, epoxy resin, polyimide (PI) or the like.

Next, the wafer 10 with the protective member 12 adhered to the upper surface 10a thereof is adhered to the center of a tape T, whose outer periphery is held by a frame F, with a lower surface 10b thereof on the lower side, whereby the wafer 10, the protective member 12 and the frame F are united together (see FIG. 1B). Note that in the protective member disposing step, the wafer 10 may first be adhered to the tape T supported by the frame F, and thereafter the protective member 12 may be adhered to the upper surface 10a of the wafer 10 held by the tape T. The wafer 10 held by the frame F through the tape T in this way is accommodated into a cassette case (not depicted) in which a plurality of the wafers 10 can be accommodated.

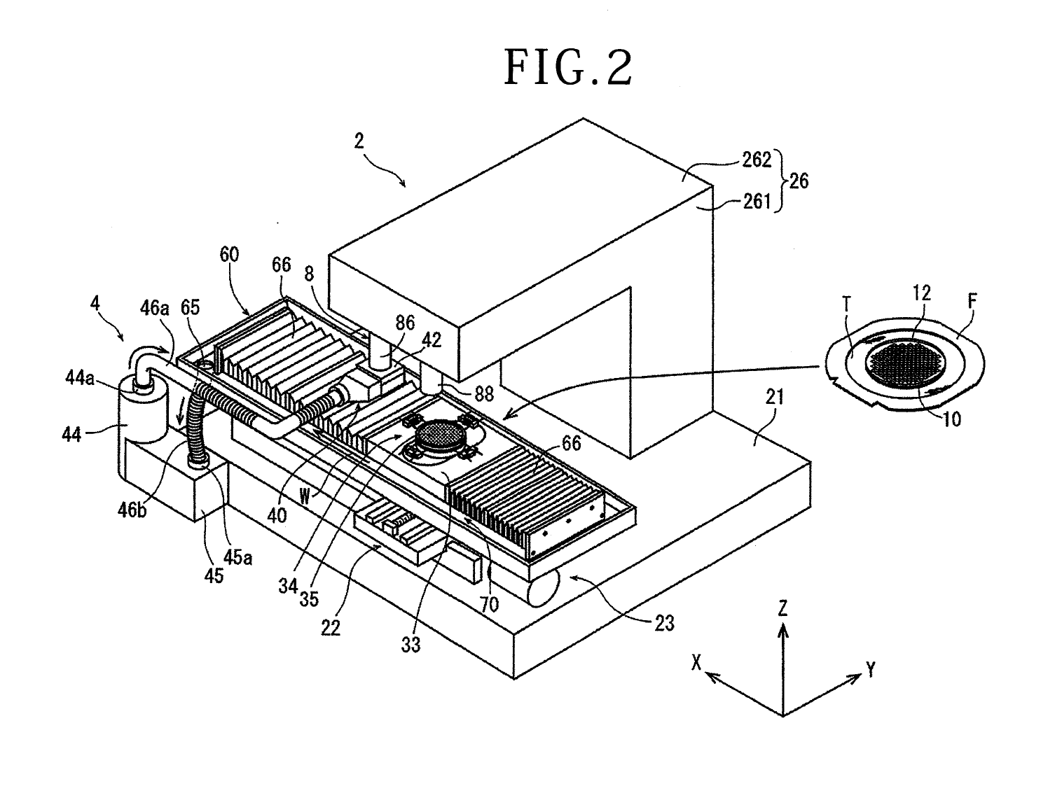

The wafer 10 subjected to the protective member disposing step is carried to a laser processing apparatus 2 illustrated in FIG. 2, where the liquid layer forming step of forming a liquid layer on the upper surface 10a of the wafer 10, the laser beam applying step of applying a laser beam through the liquid layer to subject the upper surface 10a of the wafer 10 to groove processing and to produce minute bubbles, and the debris removing step of removing debris from inside of grooves by rupture of the bubbles are carried out. The laser processing apparatus 2 will be described more in detail.

The laser processing apparatus 2 includes: holding means 22 that is disposed on a base 21 and holds the wafer 10; moving means 23 for moving the holding means 22; a frame body 26 that includes a vertical wall section 261 erectly provided in a Z direction indicated by arrow Z at a lateral side of the moving means 23 on the base 21, and a horizontal wall section 262 extending in a horizontal direction from an upper end portion of the vertical wall section 261; a liquid supplying mechanism 4; and laser beam applying means 8. As illustrated in the figure, the wafer 10 with the protective member 12 adhered thereto is supported on the annular frame F through the tape T, and is held by the holding means 22. Note that in a practical processing state, the laser processing apparatus 2 as above-mentioned is wholly covered by a housing or the like, which is omitted for convenience of description, such that dust or the like would not enter the inside of the apparatus.

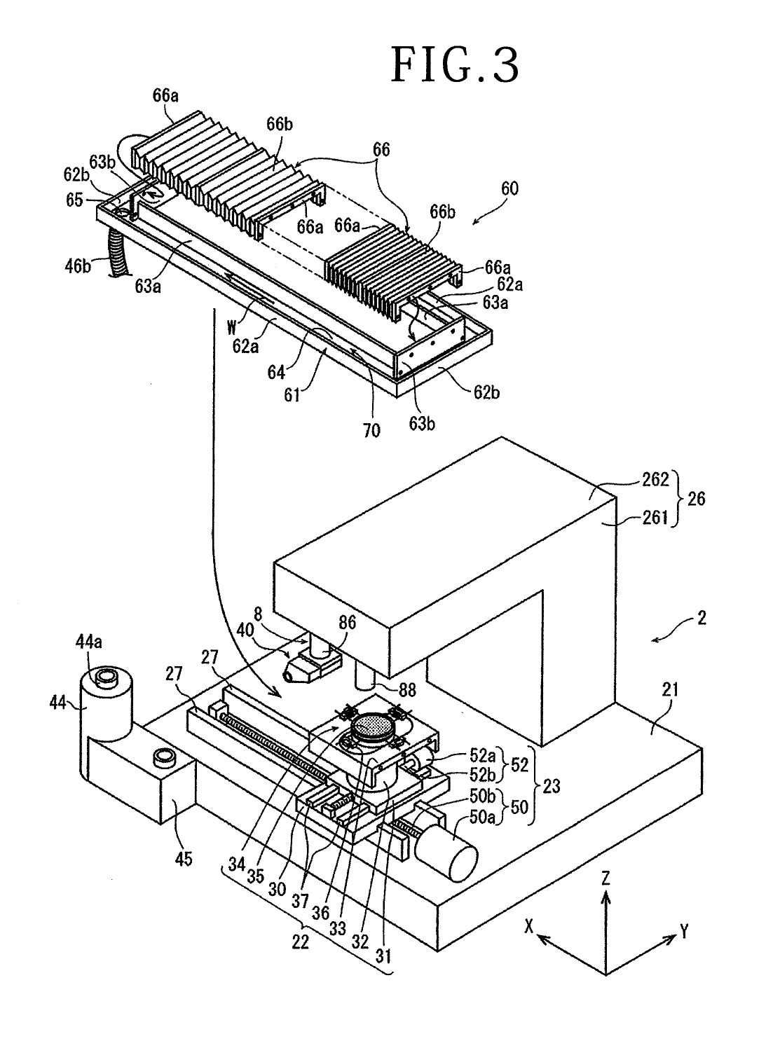

FIG. 3 is a perspective view of the laser processing apparatus 2 described in FIG. 2, depicting a state in which a liquid recovery pool 60 constituting a part of the liquid supplying mechanism 4 is detached from the laser processing apparatus 2 and is dismantled.

Referring to FIG. 3, the laser processing apparatus 2 will be described more in detail. An optical system constituting the laser beam applying means 8 for applying a laser beam to the wafer 10 held by the holding means 22, through the protective member 12, is disposed inside the horizontal wall section 262 of the frame body 26. A focusing unit 86 constituting a part of the laser applying mechanism 8 is disposed on the lower surface side of a tip portion of the horizontal wall section 262, and alignment means 88 is disposed at a position adjacent to the focusing unit 86 in a direction indicated by arrow X.

The alignment means 88 includes an imaging element (charge coupled device (CCD)) using a visible beam for imaging the upper surface 10a of the wafer 10 through the protective member 12. Note that depending on the materials constituting the wafer 10 and the protective member 12, the alignment means 88 may include infrared radiation (IR) ray applying means for applying IR rays, an optical system that captures the IR rays applied by the IR ray applying means, and an imaging element (IR CCD) that outputs an electrical signal corresponding to the IR rays captured by the optical system.

The holding means 22 includes: a rectangular X-direction movable plate 30 mounted on the base 21 such as to be movable in the X direction indicated by arrow X in FIG. 3; a rectangular Y-direction movable plate 31 mounted on the X-direction movable plate 30 such as to be movable in the Y direction indicated by arrow Y; a cylindrical support column 32 fixed to an upper surface of the Y-direction movable plate 31; and a rectangular cover plate 33 fixed to an upper end of the support column 32. A chuck table 34 extending upward through a slot formed over the cover plate 33 is disposed on the cover plate 33. The chuck table 34 is configured to hold the wafer 10 and to be rotatable by rotational driving means (not depicted). A circular suction chuck 35 formed from a porous material and extending substantially horizontally is disposed on an upper surface of the chuck table 34. The suction chuck 35 is connected to suction means (not depicted) by a flow path passing through the support column 32, and four clamps 36 are evenly arranged in the periphery of the suction chuck 35. The clamps 36 clamp the frame F that holds the wafer 10. The X direction is the direction indicated by arrow X in FIG. 3, the Y direction is the direction indicated by arrow Y and orthogonal to the X direction. A plane defined by the X direction and the Y direction is substantially horizontal.

The moving means 23 includes X-direction moving means 50 and Y-direction moving means 52. The X-direction moving means 50 converts a rotational motion of a motor 50a into a rectilinear motion, and transmits the rectilinear motion to the X-direction movable plate 30, through a ball screw 50b, thereby causing the X-direction movable plate 30 to advance or retreat in the X direction along guide rails 27, rails 27 on the base 21. The Y-direction moving means 52 converts a rotational motion of a motor 52a into a rectilinear motion, and transmits the rectilinear motion to the Y-direction movable plate 31, through a ball screw 52b, thereby causing the Y-direction movable plate 31 to advance or retreat in the Y direction along guide rails 37, rails 37 on the X-direction movable plate 30. Note that though omitted from illustration, the X-direction moving means 50 and the Y-direction moving means 52 are respectively provided with position detecting means, such that the X-directional position, the Y-directional position and the circumferential-directional rotational position of the chuck table 34 are accurately detected, and, by driving the X-direction moving means 50, the Y-direction moving means 52 and the rotational driving means (not depicted), the chuck table 34 can be accurately positioned at an arbitrary position and an arbitrary angle. The X-direction moving means 50 as above is processing feeding means for moving the holding means 22 in a processing feeding direction, and the Y-direction moving means 52 as above is indexing feeding means for moving the holding means 22 in an indexing feeding direction.

Referring to FIGS. 2 to 4B, the configuration of the liquid supplying mechanism 4 will be described. As illustrated in FIG. 2, the liquid supplying mechanism 4 includes: a liquid jetting unit 40; a liquid supply pump 44; a filter 45; the liquid recovery pool 60; a pipe 46a connecting the liquid jetting unit 40 and the liquid supply pump 44; and a pipe 46b connecting the liquid recovery pool 60 and the filter 45. Note that the pipe 46a and the pipe 46b may each be formed of a flexible hose, partly or entirely.

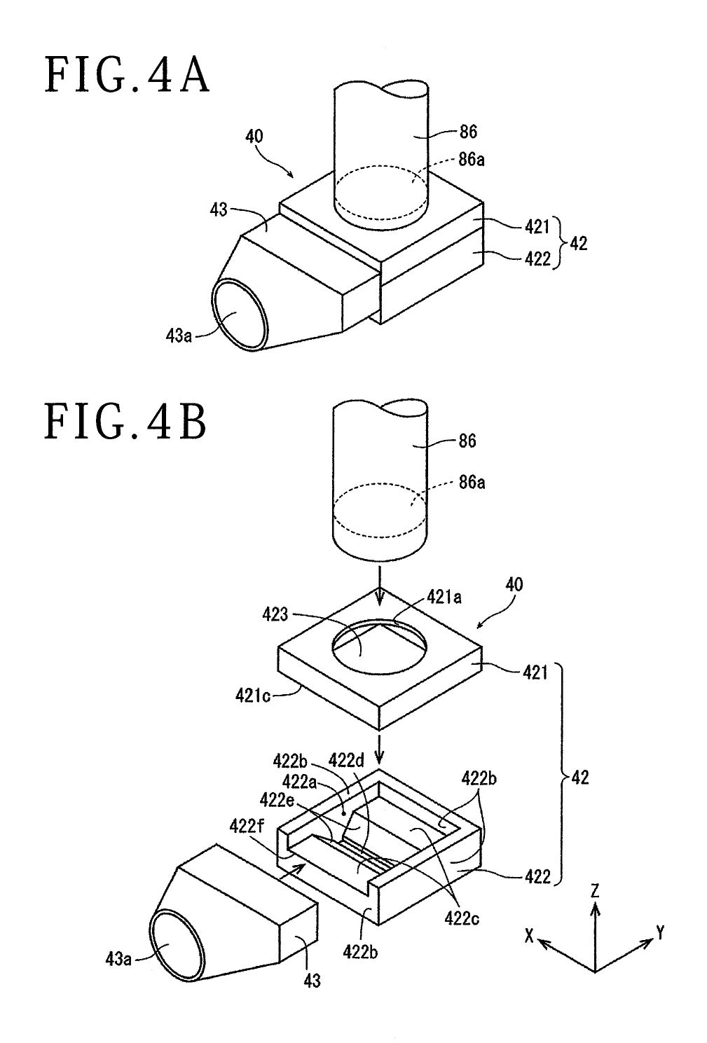

As depicted in FIG. 4A, the liquid jetting unit 40 is disposed at a lower end portion of the focusing unit 86. An exploded view of the liquid jetting unit 40 is depicted in FIG. 4B. As seen from FIG. 4B, the liquid jetting unit 40 includes a casing 42, and a liquid supplying section 43. The casing 42 is substantially rectangular in plan view, and includes a casing upper member 421 and a casing lower member 422. The casing upper member 421 is formed in a central portion of an upper surface thereof with a circular opening 421a for connecting the focusing unit 86. In addition, a transparent plate 423 permitting transmission therethrough of a laser beam LB applied from the focusing unit 86 is disposed at a lower surface 421c of the casing upper member 421. The transparent plate 423 is composed, for example, of a glass plate, closes the lower surface 421c side of the casing upper member 421, and is disposed at a position for facing the opening 421a. The casing lower member 422 includes side walls 422b and a bottom wall 422c. The side walls 422b and the bottom wall 422c define a space 422a inside the casing lower member 422. The bottom wall 422c is formed in the center thereof with an opening 422d extending in the X direction indicated by arrow X in the figure, and is formed with inclined portions 422e along both sides in regard of the longitudinal direction of the opening 422d. The width of the opening 422d is set at approximately 1 to 2 mm. The side wall 422b on the viewer's side in the Y direction indicated by arrow Y, to which the liquid supplying section 43 is connected, is formed with a liquid supply port 422f. The casing upper member 421 as above and the casing lower member 422 as above are coupled together from the upper and lower sides, whereby the casing 42 having the space 422a defined by a ceiling wall composed of the transparent plate 48, the side walls 422b and the bottom wall 422c is configured.

The liquid supplying section 43 includes: a supply port 43a where a liquid W is supplied; a discharge port (omitted from illustration) formed at a position for facing the liquid supply port 422f formed in the casing 42; and a communication passage (omitted from illustration) providing communication between the supply port 43a and the discharge port. The liquid supplying section 43 is assembled onto the casing 42 from the viewer's side in regard of the Y direction, whereby the liquid jetting unit 40 is formed.

In the liquid jetting unit 40, which has the configuration as above-mentioned, the liquid W discharged from the liquid supply pump 44 is supplied to the supply port 43a of the liquid supplying section 43, is supplied through the communication passage inside the liquid supplying section 43 and the discharge port to the liquid supply port 422f of the casing 42, and, by passing through the space 422a in the casing 42, is jetted from the opening 422d formed in the bottom wall 422c. In the liquid jetting unit 40, as depicted in FIG. 2, the liquid supplying section 43 and the casing 42 are mounted to a lower end portion of the focusing unit 86 in such a manner as to be aligned in the Y direction. As a result, the opening 422d formed in the bottom wall 422c of the casing 42 is positioned such as to extend in the X direction, which is the processing feeding direction.

Returning to FIGS. 2 and 3, the liquid recovery pool 60 will be described. As illustrated in FIG. 3, the liquid recovery pool 60 includes an outer frame body 61 and two waterproof covers 66.

The outer frame body 61 includes: outside walls 62a extending in the X direction indicated by arrow X in the figure; outside walls 62b extending in the Y direction indicated by arrow Y in the figure; inside walls 63a and 63b disposed on the inner side of the outside walls 62a and 62b with a spacing therebetween and in parallel to the outside walls 62a and 62b; and a bottom wall 64 connecting lower edges of the outside walls 62a and 62b, and the inside walls 63a and 63b. The outside walls 62a and 62b, the inside walls 63a and 63b and the bottom wall 64 form a liquid recovery passage 70 having a rectangular shape of which the long sides extend along the X direction and short sides extend along the Y direction. On the inner side of the inside walls 63a and 63b constituting the liquid recovery passage 70, an opening is formed which penetrates in the vertical direction. The bottom wall 64 constituting the liquid recovery passage 70 is provided with slight inclinations in the X direction and the Y direction, and a drain hole 65 is disposed at a corner portion (the corner portion on the left side in the figure) which is at the lowest position of the liquid recovery passage 70. A pipe 46b is connected to the drain hole 65, for connection to the filter 45 through the pipe 46b. Note that the outer frame body 61 is preferably formed from a plate material of stainless steel highly resistant against corrosion or rusting.

The two waterproof covers 66 each include two gate-formed metallic fixtures 66a, and a resin-made cover member 66b which is bellows-shaped and waterproof. The metallic fixtures 66a are formed in such a size as to be able to straddle the two inside walls 63a disposed to face each other in the Y direction of the outer frame body 61, and are attached to both end portions of the cover member 66b. One-side ones of the metallic fixtures 66a of the two waterproof covers 66 are respectively fixed to the inside walls 63b disposed to face each other in the X direction of the outer frame body 61. The liquid recovery pool 60 configured in this way is fixed onto the base 21 of the laser processing apparatus 2 by fixtures (not depicted). The cover plate 33 of the holding means 22 is mounted in the manner of being clamped between the metallic fixtures 66a of the two waterproof covers 66. Note that end faces in regard of the X direction of the cover plate 33 have the same gate form as that of the metallic fixtures 66a, and have such a size as to straddle the facing inside walls 63a of the outer frame body 61 in the Y direction, like the metallic fixtures 66a. Therefore, the cover plate 33 is mounted to the waterproof covers 66, after the outer frame body 61 of the liquid recovery pool 60 is disposed on the base 21. According to the above-described configuration, when the cover plate 33 is moved in the X direction by the X-direction moving means 50, the cover plate 33 is moved along the inside walls 63a of the liquid recovery pool 60. Note that the method of mounting the waterproof covers 66 and the cover plate 33 is not limited to the above-mentioned procedure; for example, a procedure may be adopted in which prior to the mounting of the two waterproof covers 66 to the inside walls 63b of the outer frame body 61, the cover plate 33 is preliminarily mounted, and the waterproof covers 66 are mounted to the outer frame body 61 precedingly mounted on the base 21.

Returning to FIG. 2 to continue the description, in the liquid supplying mechanism 4, which has the above-described configuration, the liquid W discharged from a discharge port 44a of the liquid supply pump 44 is supplied through the pipe 46a to the liquid jetting unit 40. The liquid W supplied to the liquid jetting unit 40 is jetted downward from the opening 422d formed in the bottom wall of the casing 42 of the liquid jetting unit 40. The liquid W jetted from the liquid jetting unit 40 is recovered in the liquid recovery pool 60. The liquid W recovered in the liquid recovery pool 60 flows through the liquid recovery passage 70, and is collected into the drain hole 65 provided at the lowest position of the liquid recovery passage 70. The liquid W collected into the drain hole 65 is led through the pipe 46b to the filter 45, by which laser processing swarf (debris) and dust and the like are removed from the liquid W, and the liquid W is returned to the liquid supply pump 44. In this way, the liquid W discharged by the liquid supply pump 44 is circulated in the liquid supplying mechanism 4.

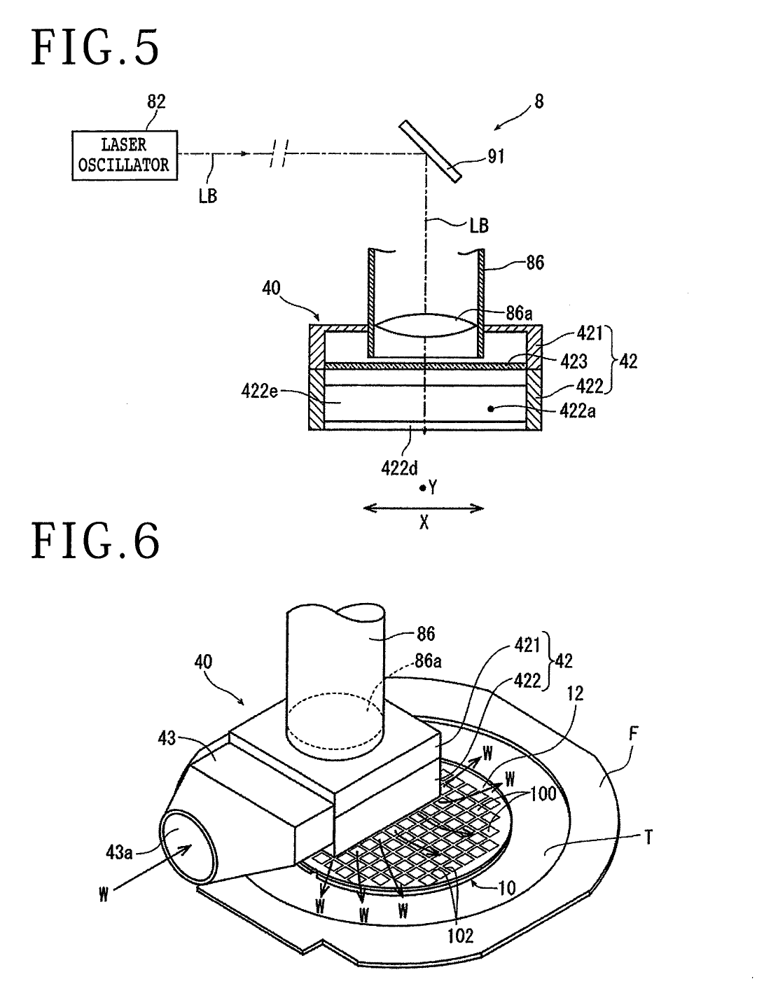

FIG. 5 depicts a block diagram of an optical system of the laser beam applying means 8 for leading the laser beam LB to the liquid jetting unit 40, together with a section taken in the X direction such as to pass through the focusing unit 86. As depicted in FIG. 5, the laser beam applying means 8 includes: an oscillator 82 that oscillates a pulsed form laser beam LB; a reflection mirror 91 that appropriately change the optical path of the laser beam LB oscillated from the oscillator 82; and the focusing unit 86. The oscillator 82 oscillates a laser beam LB of such a wavelength as to be absorbed in the wafer 10, and includes an attenuator or the like (omitted from illustration) for adjusting the output of the laser beam LB oscillated. The laser beam LB oscillated from the oscillator 82 has its optical path changed by the reflection mirror 91, is focused by a focusing lens 86a provided in the focusing unit 86, and is applied downward through the transparent plate 423, the space 422a inside the casing 42, and the opening 422d. Note that a polygon mirror rotated at high speed may be disposed in place of the above-mentioned reflection mirror 91. Where the laser beam LB is reflected by the rotating polygon mirror in such a manner as to reciprocate within the opening 422d formed to extend in the X direction, laser processing can be performed more efficiently.

Further, the laser beam applying means 8 includes focal point position adjusting means (not depicted). Though a specific configuration of the focal point position adjusting means is omitted from illustration, it includes driving means by which the position of the focal point of the laser beam LB focused by the focusing unit 86 is adjusted in the vertical direction.

Returning to FIG. 2 to continue the description, the alignment means 88 mounted with a space from the focusing unit 86 in the X direction is disposed on a lower surface of a tip portion of the horizontal wall section 262, together with the focusing unit 86. The alignment means 88 is utilized for imaging the workpiece held by the holding table 32, detecting a region to be subjected to laser processing, and aligning the focusing unit 86 and a processing position for the wafer 10. The laser processing apparatus 2 generally has the configuration as described above, and a specific mode carrying out steps subsequent to the above-mentioned protective member disposing step will be described below.

### [Liquid Layer Forming Step]

The wafer 10 with the protective member 12 disposed thereon by the above-mentioned protective member disposing step is mounted at a predetermined position of the laser processing apparatus 2 in the state of being accommodated in the cassette case (not depicted). The wafer 10 is carried out from the cassette case, is placed on the suction chuck 35 of the chuck table 34 in a state in which the upper surface 10a with the protective member 12 adhered thereto is on the upper side, and the suction source (not depicted) is operated to generate a suction force, thereby suction holding the wafer 10 onto the chuck table 34. Further, the frame F holding the wafer 10 is fixed by the clamps 36 or the like.

After the wafer 10 is held by the suction chuck 35, the chuck table 34 is appropriately moved in the X direction and the Y direction by the moving means 23, whereby the wafer 10 on the chuck table 34 is positioned directly beneath the alignment means 88. After the wafer 10 is positioned directly beneath the alignment means 88, the upper side of the wafer 10 is imaged by the alignment means 88. Next, based on the image of the wafer 10 picked up by the alignment means 88, alignment of the wafer 10 and the focusing unit 86 is performed by a technique such as pattern matching. Based on position information obtained by this alignment, the chuck table 34 is moved, to position the focusing unit 86 on the upper side of a processing starting position on the wafer 10. Next, the focusing unit 86 is moved in the Z-axis direction by the focal point position adjusting means (not depicted), whereby the focal point is positioned at a surface height of one end portion of the division line which is an application starting position for the laser beam LB applied to the wafer 10. As aforementioned, the liquid jetting unit 40 of the liquid supplying mechanism 4 is disposed at a lower end portion of the focusing unit 86, and a space of, for example, approximately 0.5 to 2.0 mm is formed by a lower surface of the casing lower member 422 constituting the liquid jetting unit 40 and a surface of the protective member 12 adhered to the upper surface 10a of the wafer 10.

After the alignment of the focusing unit 86 and the wafer 10 is performed by the alignment means 88, the liquid supplying mechanism 4 is replenished with a necessary and sufficient quantity of the liquid W through the liquid recovery passage 70 of the liquid recovery pool 60, and the liquid supply pump 44 is operated. As the liquid W circulated in the inside of the liquid supplying mechanism 4, there is used, for example, pure water.

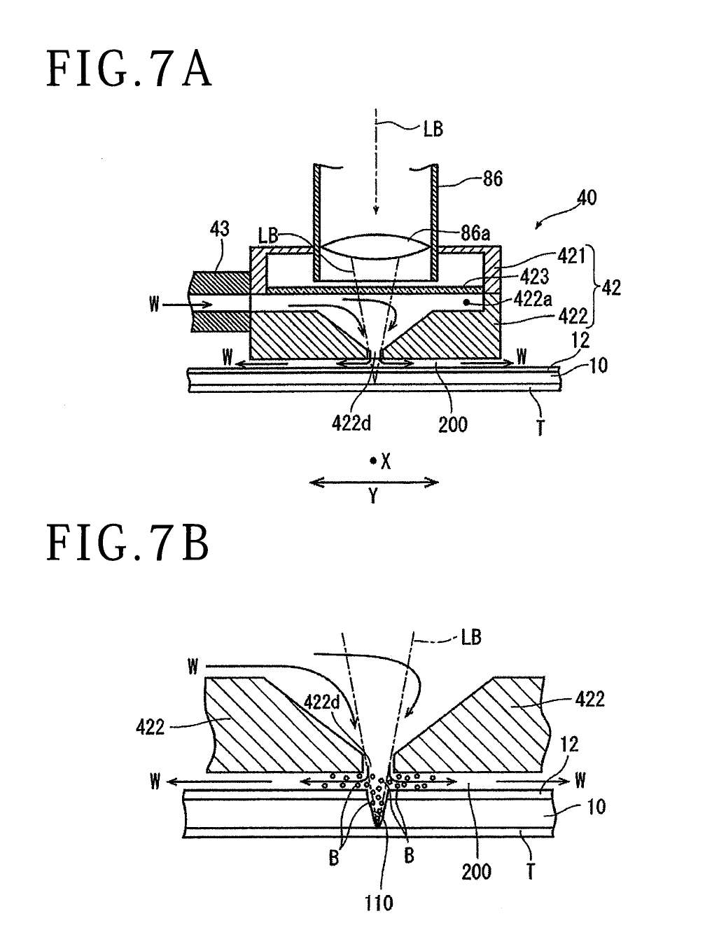

In the liquid supplying mechanism 4, which has the above-mentioned configuration, the liquid W discharged from the discharge port 44a of the liquid supply pump 44 is supplied through the pipe 46a to the supply port 43a of the liquid jetting unit 40. As depicted in FIG. 6, the liquid W supplied to the supply port 43a of the liquid jetting unit 40 is jetted downward from the casing lower member 422 of the liquid jetting unit 40. The liquid W jetted from the liquid jetting unit 40 is supplied onto the protective member 12 adhered to the upper surface 10a of the wafer 10, and flows on the protective member 12 on the wafer 10. By filling the area between the liquid jetting unit 40 and the protective member 12 with the liquid W, a liquid layer 200 is formed (see FIG. 7A as well).

After flowing on the protective member 12 on the wafer 10, the liquid W flows through the liquid recovery passage 70 of the liquid recovery pool 60, to be collected into the drain hole 65 provided at the lowest position of the liquid recovery passage 70. The liquid W collected into the drain hole 65 is led through the pipe 46b to the filter 45, by which the liquid W is cleaned, and is then returned to the liquid supply pump 44. In this way, the liquid W discharged by the liquid supply pump 44 is circulated in the liquid supplying mechanism 4, and is maintained in the state in which the liquid layer 200 is formed between the liquid jetting unit 40 and the protective member 12 (liquid layer forming step).

### [Laser Beam Applying Step]

In the state in which the liquid layer forming step is carried out by the liquid supplying mechanism 4 to form the liquid layer 200, as depicted in FIG. 7A, the X-direction moving means 50 is operated while operating the laser beam applying means 8. By this, the chuck table 34 is processing fed at a predetermined moving speed in the processing feeding direction (X direction). In this instance, as illustrated in FIG. 7A, the laser beam LB applied from the focusing unit 86 is transmitted through the transparent plate 423 of the liquid jetting unit 40, the space 422a and the liquid layer 200, and is applied to the wafer 10 through the opening 422d. While a flow of water is generated in the space 422a due to the performing of the liquid layer forming step as above-mentioned, the presence of the transparent plate 423 ensures that the laser beam LB applied from above is applied to the lower side without being influenced by the water flow.

The laser processing in the laser processing apparatus 2 as above-mentioned may be conducted, for example, under the following processing conditions.

Wavelength of laser beam: 355 nm

Average output: 3 W

Repetition frequency: 50 kHz

Processing feeding speed: 100 mm/s

While the laser beam of a wavelength of 355 nm as such a wavelength as to be transmitted through the liquid W and absorbed in the wafer 10 has been selected in the above-mentioned laser processing conditions, this is not limitative. The wavelength need only be appropriately selected from such wavelengths as to be absorbed in the material constituting the wafer 10 and to be transmitted through the liquid W, and may be selected from wavelengths of 226 nm, 355 nm, 532 nm and the like. As depicted in FIG. 7A, the laser beam LB is applied through the opening 422d formed in the casing 42 and the protective member 12 along the division line 102 formed on the upper surface 10a of the wafer 10, whereby ablation processing (groove processing) for forming a groove 110 depicted in FIG. 7B is applied to the wafer 10. When this groove processing is applied, minute bubbles (microbubbles) B are produced together with debris, in the groove 110 of the wafer 10 to which the laser beam LB is applied (laser beam applying step). Note that the microbubbles B are bubbles having diameters on the micrometer order, and the diameters are not uniform; for example, the microbubbles include bubbles with diameters of 50 μm or below.

### [Debris Removing Step]

The microbubbles B generated in the groove 110 by the application of the laser beam LB stir the inside of the groove 110, and rupture of the microbubbles B removes the debris which is liable to adhere to inside walls of the groove 110 in the manner like cavitation (debris removing step). Besides, as depicted in FIG. 7B, the liquid W is constantly supplied at a predetermined flow velocity, and the liquid layer 200 is being formed, in a gap formed over the wafer 10. By this, the microbubbles B generated in the vicinity of the applying position of the laser beam LB are pushed out from the groove 110 formed in the wafer 10 to the exterior together with the liquid W. After the laser beam applying step and the debris removing step are conducted from a processing starting position to a processing ending position of a predetermined division line, the moving means 23 is operated to perform indexing feeding in the Y direction, and the same laser beam applying step and debris removing step as above-described are conducted with respect to an adjacent unprocessed division line. Further, the wafer 10 is rotated by 90 degrees by the rotational driving means (not depicted), whereby the above-described laser beam applying step and debris removing step are carried out with respect to all the division lines 102 formed on the wafer 10.

In the present embodiment, the protective member 12 is adhered onto the wafer 10 by carrying out the protective member disposing step. As aforementioned, the laser beam applying step and the debris removing step are conducted while the liquid W is constantly flowing at a predetermined flow velocity, and the liquid layer 200 is being formed, in the gap formed on the wafer 10. For this reason, adhesion of debris to the upper surface 10a of the wafer 10 can be restrained, without adhering the protective member 12. However, when the laser beam applying step for performing groove processing is carried out by forming the liquid layer 200 on the upper surface 10a of the wafer 10 as above-described, the formation of the groove 110 is attended by the generation of microbubbles B in the groove 110, as illustrated in FIG. 7B. When discharged from the groove 110, the microbubbles B cross the optical path of the laser beam LB, and part of the laser beam LB may be scattered by the microbubbles B, possibly damaging the outer peripheries on the upper surface 10a side of the devices 100. In the laser processing method according to the present embodiment, the presence of the protective member 12 on the upper surface 10a of the wafer 10 has an effect to restrain the problem of damaging of the outer peripheries of the devices 100, even if the microbubbles B cross the optical path of the laser beam LB to cause scattering of the laser beam LB. In other words, the protective member 12 is disposed for the purpose different from that in the technology described in the above-mentioned Japanese Patent Laid-open No. 2004-188475, and depicts a novel operation and effect.

After the laser beam applying step and the debris removing step are carried out with respect to all the division lines of the wafer 10 as above-mentioned, the wafer 10 can be carried to and accommodated into the cassette, or can be carried to the subsequent step to perform a dividing step of dividing the wafer 10 by applying an external force thereto.

As seen from FIG. 2, the liquid W containing the above-mentioned microbubbles B and the debris flows on the cover plate 33 and the waterproof covers 66, and is led to the liquid recovery passage 70. The liquid W led to the liquid recovery passage 70 flows through the liquid recovery passage 70 while releasing the microbubbles B generated by ablation processing to the exterior, and is drained through the drain hole 65 formed in the lowermost portion of the liquid recovery passage 70. The liquid W drained through the drain hole 65 is led through the pipe 46b to the filter 45, and is supplied again to the liquid supply pump 44. In this way, the liquid W is circulated in the liquid supplying mechanism 4, whereby the debris and dust and the like are appropriately captured by the filter 45, the liquid W is maintained in a clean state, and the above-described laser processing method is carried out continuedly.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing method for performing groove processing by applying to a workpiece a laser beam of such a wavelength as to be absorbed in the workpiece, the laser processing method comprising:
a protective member disposing step of disposing a protective member on an upper surface of the workpiece;
a liquid layer forming step of forming a liquid layer on an upper surface of the protective member disposed on the upper surface of the workpiece, after the protective member disposing step is performed;
a laser beam applying step of applying the laser beam through the liquid layer to subject the upper surface of the workpiece to groove processing and to produce minute bubbles; and
a debris removing step of removing debris from inside of grooves by rupture of bubbles.

2. The laser processing method according to claim 1, wherein
the workpiece is a wafer in which a plurality of devices are formed on an upper surface while partitioned by a plurality of intersecting division lines, and
the laser beam applying step includes applying the laser beam along the division lines.

3. The laser processing method according to claim 1, wherein
the laser beam applying step includes applying the laser beam through a transparent plate disposed on an upper side of the liquid layer.
